(19) United States
(12) Patent Application Publication
(10) Pub. No.: US 2003/0040195 A1
(43) Pub. Date: Feb. 27, 2003

(54) Method for fabricating low dielectric constant material film

(76) Inventors: Ting-Chang Chang, Hsinchu (TW); Po-Tsun Liu, Hsinchu (TW)

Correspondence Address: CHARLES C.H. WU & ASSOCIATES, Suite 710, 7700 IRVINE CENTER DRIVE, Irvine, CA, 92618-3043, US

(21) Appl. No.: 09/947,888

(22) Filed: Sep. 6, 2001

(30) Foreign Application Priority Data
Aug. 27, 2001 (TW) 90120990

(51) Int. Cl. H01L 21/31; H01L 21/469

(52) U.S. Cl. 438/782

(57) ABSTRACT

The present invention provides a method for fabricating a low dielectric constant (low-k) material film. A spin-on low-k material film is formed in a provided substrate, and a baking process is performed to the spin-on low-k material film. An energy beam is then applied evenly on the spin-on low-k material film to cure the film. The present invention can efficiently reduce leakage currents of the low-k material film by applying high-energy beams onto the low-k material to attain complete bindings.

### CROSS-REFERENCE TO RELATED APPLICATION

This application claims the priority benefit of Taiwan application serial no. 90120990, filed Aug. 27, 2001.

### BACKGROUND OF THE INVENTION

1. Field of the Invention

The present invention relates to a method for fabricating semiconductor devices. More particularly, the present invention relates to a method of fabricating a low dielectric constant (low-k) material film.

2. Description of the Related Art

Metal lines (wires) are commonly used for electrically connecting various devices in the semiconductor manufacture processes. The metal lines are connected to the semiconductor devices through contacts, while the metal lines are connected through interconnects. As the ICs enter into the sub-micron processes, along with higher integration and shorter distances between metal lines, time delay of electrical signals between the metal lines (i.e. RC delay) becomes the major reason of limiting the speed of the device. Therefore, in order to solve parasitic capacitance problems resulting from minimizing the line-width, low dielectric constant (k) materials with a dielectric constant lower than silicon dioxide (k=3.9) have been developed and widely used.

The prior art methods for fabricating low-k material layers include chemical vapor deposition (CVD) and spin-coating deposition (SOD). SOD has advantages like, low-cost and efficiency, thus being widely used in the semiconductor manufacture processes Between many materials with low dielectric constants, Si—O based materials including organic high-molecular-weight compounds, such as, hydrogen silsesquioxane (HSQ, with k=2.8-3.0), methyl-silsesquioxane (MSQ, with k=2.5-2.7), hybrid organic siloxane polymer (HOSP, k=2.5) and porous silicate (k<2.0), are considered useful and valuable.

Since the low k dielectric materials usually are used as the inter-metal dielectrics (IMD) for the interconnect structure, the low-k materials need to have low film leakage currents to achieve good isolation, except for the low dielectric constant.

On the other hand, low-k materials obtained from SOD usually contain large amounts of solvents. The prior art method for removing solvents from SOD dielectrics is to cure the film in the furnace with nitrogen and hydrogen gases. However, if the curing process is incomplete, the solvents and impurities contained in the film can not be removed completely and incomplete bindings exist in the film, thus resulting in higher film leakage currents.

### SUMMARY OF THE INVENTION

According to above, the invention provides a method for fabricating a low dielectric constant (low-k) material film. By applying with high-energy beams, the low-k dielectric film can attain complete bindings, thus reducing leakage currents.

The present invention provides a method for fabricating a low dielectric constant (low-k) material film. A spin-on low-k material film is formed in a provided substrate, and a baking process is performed to the spin-on low-k material film. An energy beam is then applied evenly on the spin-on low-k material film to cure the film.

As embodied and described broadly herein, the energy beam applying on the spin-on low-k material film can be x-rays, short electromagnetic waves, electron-beams or ion-beams with an energy density of about 10 watt/cm² to 70 watt/cm².

Therefore, the present invention can efficiently reduce leakage currents of the low-k material film by applying energy beams to the low-k material to attain complete bindings after spin coating the low-k material over the substrate and performing primary baking.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings,

FIG. 1A through FIG. 1B are schematic, cross-sectional views showing process steps for forming a low-k material film according to one preferred embodiment of the invention; and

FIG. 2 is a diagram showing characteristics of leakage currents for HSQ films with different curing processes according to one preferred embodiment of the invention.

### DESCRIPTION OF THE PREFERRED EMBODIMENTS

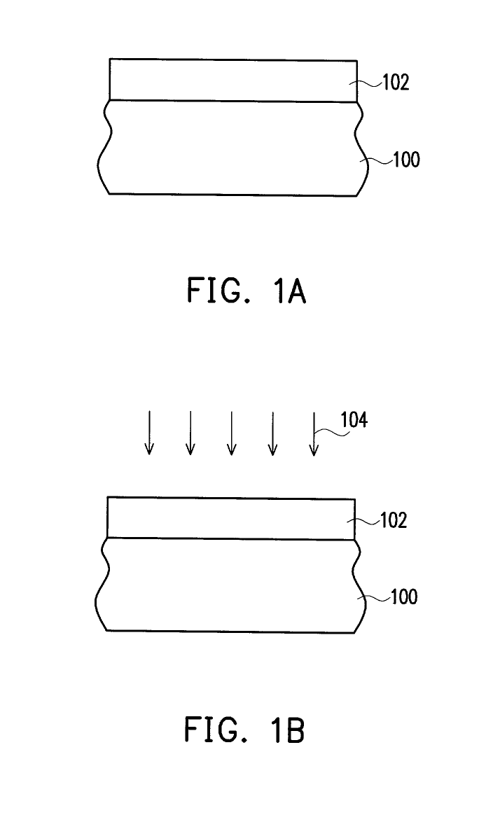

FIG. 1A through FIG. 1B are schematic, cross-sectional views showing process steps for forming a low-k material film according to one preferred embodiment of the invention

As shown in FIG. 1A, a substrate 100 is provided. A spin-on low-k material film 102 is formed on the substrate 100. The spin-on low-k material film 102 is preferably formed of low-k dielectric materials, for example, hydrogen silsesquioxane (HSQ), methyl-silsesquioxane (MSQ, with k=2.5-2.7), hybrid organic siloxane polymer (HOSP, k=2.5) or porous silicate (k<2.0), formed by spinning on.

Afterwards, a baking process is performed. The substrate 100 is placed on a hot plate and baked for one minute sequentially under 100° C., 200° C. and 300° C.

Referring to FIG. 1B, an energy beam 104 is applied evenly onto the spin-on low-k material film 102. The applied energy beam 104 can be, for example, X-ray, short electromagnetic waves, electron-beam or ion-beam, with an energy density of about 10 watt/cm² to about 70 watt/cm² and an application time of about 10 minutes to 60 minutes. As the energy beam applied evenly to the spin-on low-k material film 102, energy of the energy beam 104 is strong enough to make the spin-on low-k material film 102 attain complete bindings. So that the cage-like film structure of the spin-on low-k material film 102 can change into a network structure, thus efficiently reducing leakage currents of the spin-on low-k material film 102.

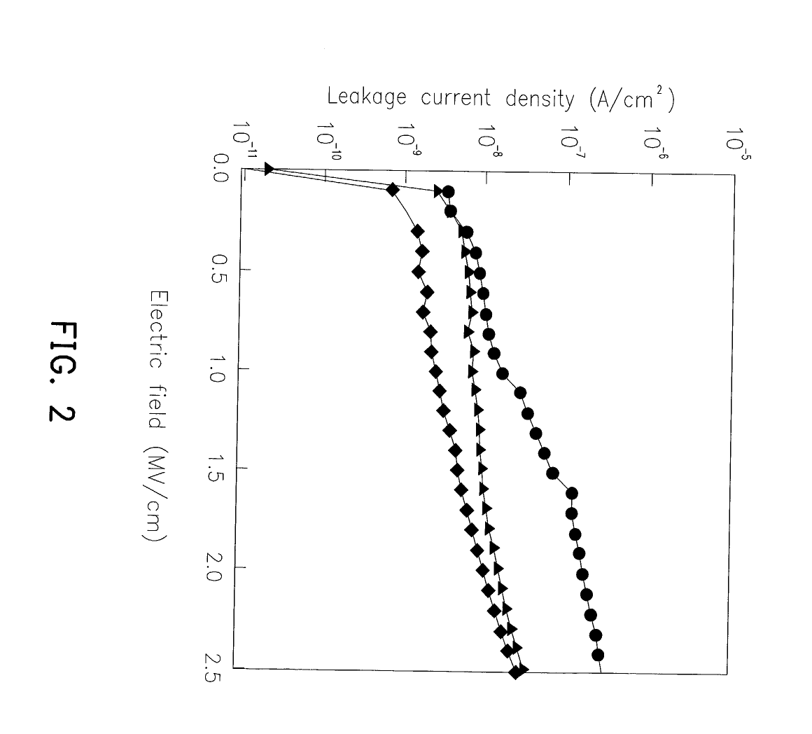

In order to describe the present invention in details, the HSQ film cured by X-ray with an energy density of 14 watt/cm² is used as Example 1 and the HSQ film cured by X-ray with an energy density of 28 watt/cm² is used as Example 2. The HSQ film cured by the prior art method under 400° C. in the furnace with nitrogen and hydrogen gases for an hour is taken as Control 1. Characteristics of the leakage currents of the HSQ films in Example 1, 2 and Control 1 are measured and plotted respectively in FIG. 2. In FIG. 2, Example 1, Example 2 and Control 1 are represented respectively as (-▴-), (-♦-) and (-●-). As shown in FIG. 2, under the same electrical field conditions, the HSQ cured by the X-ray with the energy density of 28 watt/cm² has the lowest leakage current, while the HSQ film cured by the prior art method under 400° C. in the furnace with nitrogen and hydrogen gases for one hour has the highest leakage current. Therefore, compared with the prior art method, the method disclosed in the present invention can efficiently reduce the leakage current of the spin-on low-k material film.

The present invention can efficiently reduce leakage currents of the low-k material film by applying high energy beams onto the low-k material to attain complete bindings after spin coating the low-k material over the substrate and performing primary baking.

Other embodiments of the invention will appear to those skilled in the art from consideration of the specification and practice of the invention disclosed herein. It is intended that the specification and examples be considered as exemplary only, with a true scope and spirit of the invention being indicated by the following claims.

What is claimed is:

1. A method for forming a low dielectric constant material film, comprising:
providing a substrate;
forming a spin-on low dielectric constant material film on the substrate;
performing a baking process to the spin-on low dielectric constant material film; and
applying an energy beam evenly onto the spin-on low dielectric constant material film, in order to cure the spin-on low dielectric constant material film.

2. The method of claim 1, wherein the energy beam has an energy density of 10 watt/cm² to 70 watt/cm².

3. The method of claim 1, wherein the energy beam comprises X-ray.

4. The method of claim 1, wherein the energy beam comprises short electromagnetic waves.

5. The method of claim 1, wherein the energy beam comprises electron-beam.

6. The method of claim 1, wherein the energy beam comprises ion-beam.

7. The method of claim 1, wherein a material of the spin-on low dielectric constant material film is selected from the following group consisting of hydrogen silsesquioxane (HSQ) methyl-silsesquioxane (MSQ), hybrid organic siloxane polymer (HOSP) and porous silicate.

8. A method for forming a low dielectric constant material film, comprising:
forming a spin-on low dielectric constant material film on a substrate; and
performing a curing process to the spin-on low dielectric constant material film by using an energy beam evenly onto the spin-on low dielectric constant material film with an energy beam has an energy density of 10 watt/cm² to 70 watt/cm².

9. The method of claim 8, wherein the energy beam comprises X-ray.

10. The method of claim 8, wherein the energy beam comprises short electromagnetic waves.

11. The method of claim 8, wherein the energy beam comprises electron-beam.

12. The method of claim 8, wherein the energy beam comprises ion-beam.

13. The method of claim 8, wherein a material of the spin-on low dielectric constant material film is selected from the following group consisting of hydrogen silsesquioxane (HSQ) methyl-silsesquioxane (MSQ), hybrid organic siloxane polymer (HOSP) and porous silicate.
